(19) United States
(12) Patent Application Publication
(10) Pub. No.: US 2003/0147224 A1
(43) Pub. Date: Aug. 7, 2003

(54) Computer enclosure with pivotable hood

(76) Inventor: Yun-Lung Chen, Tu-Chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/112,925

(22) Filed: Mar. 29, 2002

(30) Foreign Application Priority Data
Feb. 6, 2002 (TW) 91201371

(51) Int. Cl. H05K 5/00; H05K 5/04; H05K 5/06

(52) U.S. Cl. 361/752

(57) ABSTRACT

A computer enclosure includes a base (20), a hood (10), a pair of linking mechanisms (30) pivotably connected between the base and the hood, and a pair of lock devices (40) fixed to the hood and engagable with the base. The base includes a bottom panel (22) and a pair of side panels (24) extending from the bottom panel. The hood includes a top cover (12) and a pair of sidewalls (16) extending from the top cover. Each linking mechanism includes a first support member (64) fixed to the hood, a second support member (66) fixed to the base, a third support member (67) fixed to the base, a first rod (32) pivotably connected with the first support member and pivotably and slidably connected with the second support member, and a second rod (34) pivotably connected with the first rod and with the third support member.

### BACKGROUND OF THE INVENTION

1. Field of the Invention

The present invention relates to computer enclosures, and particularly to a computer enclosure having a base and a hood pivotable about the base.

2. Related Art

An electronic device such as a computer normally includes an enclosure for receiving and protecting internal electronic components and subassemblies. The enclosure can also protect other adjacent electronic devices from electromagnetic interference. An enclosure should be able to readily receive new or replacement electronic components and/or subassemblies therein. An enclosure that can be readily assembled and disassembled saves time and reduces costs.

Contemporary computers have a variety of enclosures. One kind of conventional enclosure, as disclosed in Taiwan Patent Application No. 89211639, includes a base and a hood attached to the base with bolts. It is time-consuming and laborious to attach the hood to the base by screwing down the bolts. Similarly, it is time-consuming and troublesome to detach the hood from the base by unscrewing the bolts. These difficulties are even more pronounced in mass production facilities. Reduced efficiency increases costs of computers.

### SUMMARY OF THE INVENTION

Accordingly, an object of the present invention is to provide a computer enclosure including a base and a hood pivotable about the base thereby facilitating assembly and maintenance of the computer.

To achieve the above-mentioned object, a computer enclosure of the present invention includes a base, a hood, a pair of linking mechanisms pivotably connected between the base and the hood, and a pair of lock devices fixed to the hood and engagable with the base. The base includes a bottom panel and a pair of side panels extending from the bottom panel. The hood includes a top cover and a pair of sidewalls extending from the top cover. Each linking mechanism includes a first support member fixed to the hood, a second support member fixed to the base, a third support member fixed to the base, a first rod pivotably connected with the first support member and pivotably and slidably connected with the second support member, and a second rod pivotably connected with the first rod and with the third support member.

Other objects, advantages and novel features of the present invention will be drawn from the following detailed description of a preferred embodiment of the present invention with attached drawings, in which:

### BRIEF DESCRIPTION OF THE DRAWINGS

FIG. 1 is an exploded perspective view of a computer enclosure in accordance with the present invention;

FIG. 2 is an enlarged perspective view of a base of the enclosure of FIG. 1, viewed from another aspect;

FIG. 3 is an enlarged perspective view of a hood of the enclosure of FIG. 1, viewed with the hood inverted; and

FIG. 4 is an assembled view of FIG. 1.

### DETAILED DESCRIPTION OF THE PREFERRED EMBODIMENT

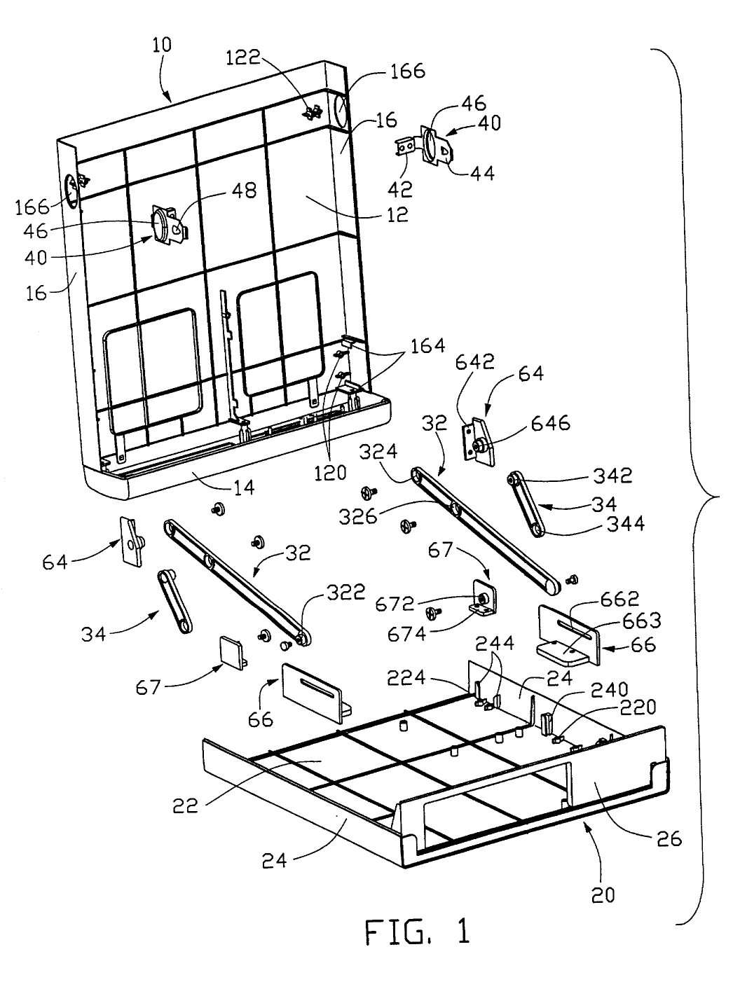

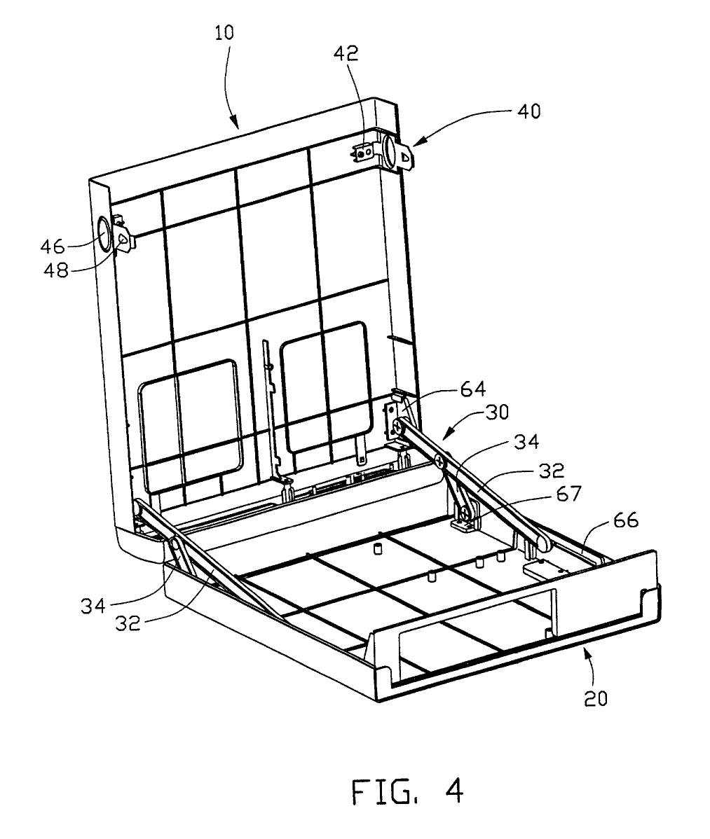

Referring to FIGS. 1 and 4, a computer enclosure in accordance with the present invention includes a base 20, a hood 10, a pair of linking mechanisms 30 pivotably connecting the hood 10 to the base 20, and a pair of lock devices 40 for locking the hood 10 to the base 20. Each linking mechanism 30 includes a first rod 32, a second rod 34 pivotably connected with the first rod 32, a first support member 64 fixed to the hood 10 and pivotably connected with the first rod 32, a second support member 66 fixed to the base 20 and pivotably and slidably connected with the first rod 32, and a third support member 67 fixed to the base 20 and pivotably connected with the second rod 34.

Each first rod 32 defines a first pivot hole 324 in an end thereof. A second pivot hole 326 is defined in the first rod 32 between the first pivot hole 324 and a central portion of the first rod 32. A first pivot 322 is outwardly formed at an opposite end of the first rod 32. A screw hole (not labeled) is defined in the first pivot 322. Each first support member 64 comprises a first fixing plate 642. Two through holes (not labeled) are defined in the first fixing plate 642, for fixing the first support member 64 to the hood 10. A fourth pivot 646 is inwardly formed from each first support member 64, for being pivotably received in the first pivot hole 324 of the corresponding first rod 32. A screw hole (not labeled) is defined in the fourth pivot 646. Each second support member 66 comprises a second fixing plate 663. Two through holes (not labeled) are defined in the second fixing plate 663, for fixing the second support member 66 to the base 20. A horizontal slot 662 is defined in the second support member 66, for pivotably and slidably receiving the first pivot 322 of the corresponding first rod 32 therein.

The second rods 34 are shorter than the first rods 32. Each second rod 34 outwardly forms a second pivot 342 at an end thereof, for being pivotably received in the second pivot hole 326 of the corresponding first rod 32. A screw hole (not labeled) is defined in the second pivot 342. A third pivot hole 344 is defined in an opposite end of the second rod 34. Each third support member 67 comprises a third fixing plate 674. Two through holes (not labeled) are defined in the third fixing plate 674, for fixing the third support member 67 to the base 20. A third pivot 672 is inwardly formed from the third support member 67, for being pivotably received in the third pivot hole 344 of the corresponding second rod 34. A screw hole (not labeled) is defined in the third pivot 672.

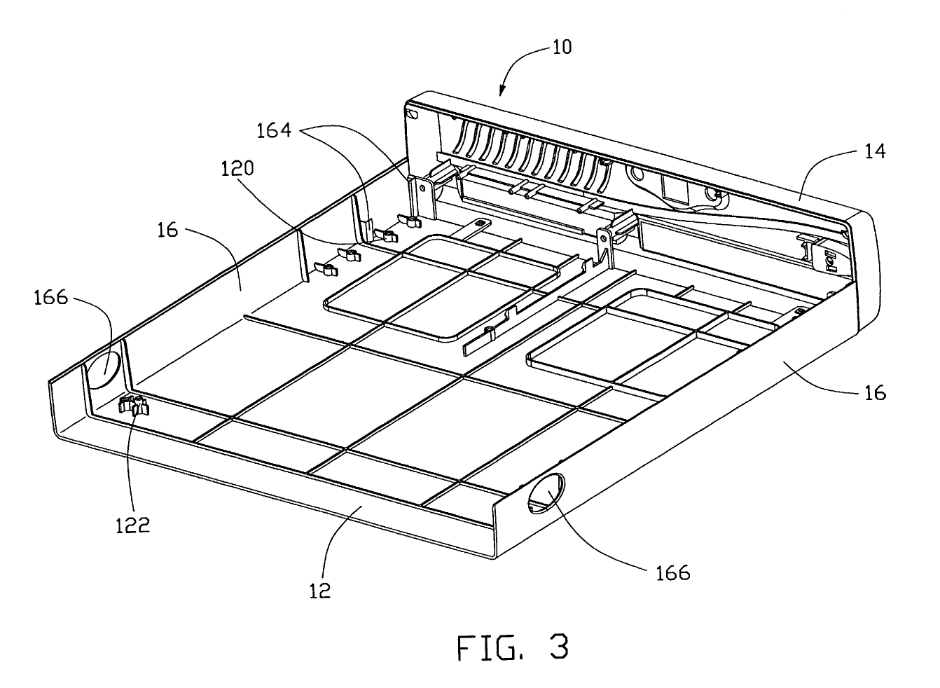

Referring to FIGS. 1 and 3, the hood 10 includes a top cover 12, a bezel 14 extending from the top cover 12, and a pair of sidewalls 16 extending from the top cover 12. A pair of first fixing posts 120 is inwardly formed from each of opposite sides of the top cover 12 at the sidewalls 16, for fixedly supporting the first support member 64 of the corresponding linking mechanism 30. A screw hole (not labeled) is defined in each first fixing post 120, corresponding to one of the through holes of the first fixing plate 642 of the corresponding first support member 64. A pair of opposing first guide rails 164 is inwardly formed from each sidewall 16 at a junction with the top cover 12, for slidingly receiving the corresponding first support member 64 therebetween. An opening 166 is defined in each sidewall 16 near an end thereof that is distal from the bezel 14. A pair of locating posts 122 is inwardly formed from the top cover 12 near each opening 166.

Each lock device 40 includes a fixing portion 42, and a latch portion 44 extending generally perpendicularly from the fixing portion 42. Each latch portion 44 outwardly forms a protrusion 48, for engaging with the base 20. A button 46 extends outwardly from each latch portion 44, for being received in the opening 166 of the corresponding sidewall 16 of the hood 10.

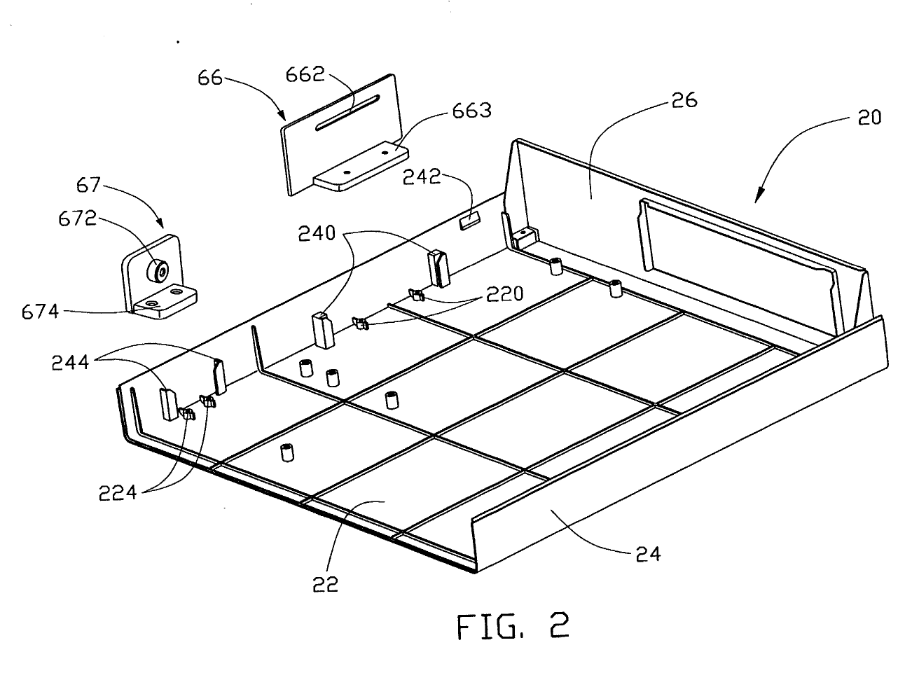

Referring to FIG. 2, the base 20 includes a bottom panel 22, a pair of side panels 24 extending from the bottom panel 22, and a rear panel 26 extending from the bottom panel 22. A pair of second fixing posts 220 is formed on each of opposite sides of the bottom panel 22 at the side panels 24, for fixedly supporting the second support member 66 of the corresponding linking mechanism 30. A screw hole (not labeled) is defined in each second fixing post 220, corresponding to one of the through holes of the second fixing plate 663 of the corresponding second support member 66. A pair of opposing second guide rails 240 is inwardly formed from each side panel 24 at a junction with the bottom panel 22, for slidingly receiving the corresponding second support member 66 therebetween. A pair of third fixing posts 224 is formed on each of opposite sides of the bottom panel 22 at the side panels 24, for fixedly supporting the third support member 67 of the corresponding linking mechanism 30. A screw hole (not labeled) is defined in each third fixing post 224, corresponding to one of the through holes of the third fixing plate 674 of the corresponding third support member 67. A pair of opposing third guide rails 244 is inwardly formed from each side panel 24 at a junction with the bottom panel 22, for slidingly receiving the corresponding third support member 67 therebetween. A pair of blocks 242 is inwardly formed from A rear portions of the side panels 24 respectively.

Referring to FIGS. 1 and 4, in assembly, the first and second support members 64, 66 are pivotably attached to the corresponding first rods 32. The second rods 34 are pivotably attached to the corresponding first rods 32. The third support members 67 are pivotably attached to the corresponding second rods 34. The first support members 64 are fixed to the hood 10, the second support members 66 are fixed to the base 20, and the third support members 67 are fixed to the base 20. The linking mechanisms 30 are thus pivotably connected between the hood 10 and the base 20. Therefore, the hood 10 is pivotable about the base 20.

The fixing portions 42 of the lock devices 40 are fixed to the corresponding locating posts 122 of the hood 10. The buttons 46 of the lock devices 40 are received in the openings 166 of the hood 10. When the hood 10 is closed, the protrusions 48 of the latch portions 44 of the lock devices 40 snappingly engage with the blocks 242 (see FIG. 2) of the base 10. The hood 10 is thereby removably attached to the base 20. When the buttons 46 of the lock devices 40 are pushed inwardly, the protrusions 48 of the lock devices 40 are disengaged from the blocks 242 of the base 10. The hood 10 is thereby pivotably released from the base 20. Thus, the hood 10 is readily rotated up from the base 20, to facilitate access to an interior of the computer enclosure.

It is understood that the invention may be embodied in other forms without departing from the spirit thereof. Thus, the present example and embodiment are to be considered in all respects as illustrative and not restrictive, and the invention is not to be limited to the details given herein. For example, a torsion spring may be installed on the third support member 67 and the second rod 34 for facilitating opening the hood 10. Moreover, alternately the pivot 322 of the first rod 32 and the slot 662 in the support member 66 may be switched, if proper.

1. A computer enclosure comprising:
a base comprising a bottom panel and a pair of side panels extending from the bottom panel;
a hood comprising a top cover and a pair of sidewalls extending from the top cover;
a pair of linking mechanisms pivotably connected between the base and the hood, each of the linking mechanisms comprising a first support member fixed to the hood, a second support member fixed to the base, a third support member fixed to the base, a first rod pivotably connected with the first support member and pivotably and slidably connected with the second support member, and a second rod pivotably connected with the first rod and the third support member; and
a pair of lock devices fixed to the hood and engagable with the base.

2. The computer enclosure as claimed in claim 1, wherein the first rod is longer than the second rod.

3. The computer enclosure as claimed in claim 1, wherein the first rod defines a first pivot hole in an end thereof, and the first rod is pivotably connected with the first support member at the first pivot hole, and wherein the first rod further defines a second pivot hole between a central portion thereof and the first pivot hole, and the first rod is pivotably connected with the second rod at the second pivot hole.

4. The computer enclosure as claimed in claim 3, wherein a first pivot is formed at an opposite end of the first rod, a slot is defined in the second support member, and the slot pivotably and slidably receives the first pivot of the first rod.

5. The computer enclosure as claimed in claim 4, wherein the second rod forms a second pivot at an end thereof, and the second pivot is pivotably connected with the first rod.

6. The computer enclosure as claimed in claim 5, wherein a third pivot hole is defined in an opposite end of the second rod, a third pivot is formed from the third support member, and the third pivot is pivotably received in the third pivot hole of the second rod.

7. The computer enclosure as claimed in claim 1, wherein the first support member comprises a first fixing plate, a pair of first fixing posts is inwardly formed from each of opposite sides of the top cover of the hood, and the first fixing posts fixedly support the first fixing plate of a corresponding first support member.

8. The computer enclosure as claimed in claim 1, wherein the second support member comprises a second fixing plate, a pair of second fixing posts is inwardly formed from each of opposite sides of the bottom panel of the base, and the second fixing posts fixedly support the second fixing plate of a corresponding second support member.

9. The computer enclosure as claimed in claim 1, wherein the third support member comprises a third fixing plate, a pair of third fixing posts is inwardly formed from each of opposite sides of the bottom panel of the base, and the third fixing posts fixedly support the third fixing plate of a corresponding third support member.

10. The computer enclosure as claimed in claim 1, wherein a pair of first guide rails is inwardly formed from each of the sidewalls of the hood at a junction with the top cover, and the first guide rails slidingly receive a corresponding first support member therebetween.

11. The computer enclosure as claimed in claim 1, wherein a pair of second guide rails is inwardly formed from each of the side panels of the base at a junction with the bottom panel, and the second guide rails slidingly receive a corresponding second support member therebetween.

12. The computer enclosure as claimed in claim 1, wherein a pair of third guide rails is inwardly formed from each of the side panels of the base at a junction with the bottom panel, and the third guide rails slidingly receive a corresponding third support member therebetween.

13. The computer enclosure as claimed in claim 1, wherein each of the lock devices comprises a fixing portion and a latch portion extending substantially perpendicularly from the fixing portion, a pair of locating posts is inwardly formed from each of opposite sides of the top cover of the hood, and the fixing portion of each of the lock devices is fixed to a corresponding pair of locating posts.

14. The computer enclosure as claimed in claim 13, wherein a pair of blocks is inwardly formed from rear portions of the side panels of the base respectively, the latch portion of each of the lock devices outwardly forms a protrusion, and the latch portion of each of the lock devices is engagable with a corresponding block of the base.

15. The computer enclosure as claimed in claim 13, wherein an opening is defined near an end of each of the sidewalls of the hood, a button extends outwardly from the latch portion of each of the lock devices, and the button is extendable into the opening of a corresponding sidewall for facilitating disengagement of the latch portion of each of the lock devices from the base.

16. A computer enclosure comprising:
a base comprising a bottom panel, and a pair of side panels extending from the bottom panel;
a hood comprising a top cover, and a pair of sidewalls extending from the top cover; and
a pair of linking mechanisms pivotably connected between the base and the hood, each of the linking mechanisms comprising a first support member fixed to the hood, a second support member fixed to the base, a third support member fixed to the base, a first rod pivotably connected with the first support member and pivotably and slidably connected with the second support member, and a second rod pivotably connected with the first rod and the third support member, wherein the first rod is longer than the second rod.

17. The computer enclosure as claimed in claim 16, wherein the first rod defines a first pivot hole in an end thereof, and the first rod is pivotably connected with the first support member at the first pivot hole, and wherein the first rod further defines a second pivot hole between a central portion thereof and the first pivot hole, and the first rod is pivotably connected with the second rod at the second pivot hole, and wherein a first pivot is formed at an opposite end of the first rod, a slot is defined in the second support member, and the slot pivotably and slidably receives the first pivot of the first rod.

18. The computer enclosure as claimed in claim 16, wherein the second rod comprises a second pivot formed at an end thereof, and the second pivot is pivotably connected with the first rod, and wherein a third pivot hole is defined in an opposite end of the second rod, and a third pivot is formed from the third support member, and the third pivot is pivotably received in the third pivot hole of the second rod.

19. The computer enclosure as claimed in claim 16, wherein the first support member comprises a first fixing plate, a pair of first fixing posts is inwardly formed from each of opposite sides of the top cover of the hood, and the first fixing posts fixedly support the first fixing plate of a corresponding first support member, and wherein the second support member comprises a second fixing plate, a pair of second fixing posts is inwardly formed from each of opposite sides of the bottom panel of the base, and the second fixing posts fixedly support the second fixing plate of a corresponding second support member, and wherein the third support member comprises a third fixing plate, a pair of third fixing posts is inwardly formed from each of the opposite sides of the bottom panel of the base, and the third fixing posts fixedly support the third fixing plate of a corresponding third support member.

20. The computer enclosure as claimed in claim 16, wherein a pair of first guide rails is inwardly formed from each of the sidewalls of the hood at a junction with the top cover, and the first guide rails slidingly receive a corresponding first support member therebetween, and wherein a pair of second guide rails is inwardly formed from each of the side panels of the base at a junction with the bottom panel, and the second guide rails slidingly receive a corresponding second support member therebetween, and wherein a pair of third guide rails is inwardly formed from each of the side panels of the base at a junction with the bottom panel, and the third guide rails slidingly receive a corresponding third support member therebetween.

21. A computer enclosure comprising:
a base comprising at least one side panel thereof;
a hood attached unto the base with at least one side wall thereof;
a linking mechanism connecting said hood to said base,
said linking mechanism including a first rod with a first pivot point around a rear end thereof pivotally attached to around a rear portion of said side wall, and a second pivot point, around a position between a mid point and said rear end thereof, pivotally attached to a front/upper end of a second rod, a rear/bottom end of said second rod pivotally attached to around a rear portion of said side panel, and
means for regulating a path of a front portion of said first rod relative to the side panel when said second rod is forwardly rotated about said rear/bottom end thereof, so as to assure a proper path of the first pivot point during said rotation.

22. The enclosure as claimed in claim 21, wherein said means includes a horizontal slot extending parallel to said side panel, and a pivot formed on the front portion of the first rod and moveably received in said slot.
